(19) United States
(12) Patent Application Publication
(10) Pub. No.: US 2007/0222375 A1
(43) Pub. Date: Sep. 27, 2007

(54) System for displaying images including electroluminescent device and method for fabricating the same

(75) Inventors: Chun-Yen Liu, Jhubei City (TW); Ryan Lee, Hualien City (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 11/386,554

(22) Filed: Mar. 22, 2006

(51) Int. Cl. H01L 51/00

(52) U.S. Cl. 313/506

(57) ABSTRACT

Systems for displaying images and fabrication method thereof are provided. A representative system incorporates an active matrix electroluminescent device that comprises a plurality of pixel area. An ink-jet printing color filter layer is formed in each pixel area. Each ink-jet printing color filter layer is surrounded with a dam. A planarization layer is formed on the pixel areas, covering the ink-jet printing color filter layers and the dams. An organic light diode, comprising an anode, electroluminescent layers, and a cathode, is formed on the planarization layer, directly over the ink-jet printing color filter layer.

### BACKGROUND

The invention relates to an organic electroluminescent device and, more particularly, to a full-color active matrix organic electroluminescent device with color filters.

Several methods have been employed to achieve full color emission in organic electroluminescent devices. In general, there is a major tendency to fabricate full color organic electroluminescent devices by a method of RGB emitting layers or a color changing method. Among these methods, the so-called “color changing method” indicates that white organic light-emitting diodes are formed respectively on corresponding red, green and blue color filters, and then driven by bias voltages to emit red, green and blue respectively.

In conventional full-color active matrix organic electroluminescent devices, the RGB color filters thereof are typically formed by a pigment dispersion process. For the pigment dispersion process, a photosensitive resin layer, wherein a pigment has been dispersed, is formed on a substrate by spin coating, and a patterning process is performed to obtain a single color pattern. Then, to produce R, G and B, color filter layers, this process is performed once for each of the colors R, G and B, i.e., the process is repeated a total of three times. Thus, the fabrication process is complicated and time-consuming. Additionally, more than 90% of the photosensitive resin is consumed during spin-coating.

Further, since the photosensitive resin serving as a color filter layer is typically a negative type photoresist, the unmasked photosensitive resin may be undesirably cross-linked through light form outside and remain in contact holes, resulting in open circuits and contact blind.

To overcome the described drawbacks, various methods for forming color filters, such as electrodeposition or dye printing, have been developed. The disclosed methods, however, are not suitable application in organic electroluminescent devices. In the electrodeposition method, limitations are imposed on pattern shapes which can be formed. In the dry printing method, a pattern with a fine pitch is difficult to form due to poor resolution and poor surface roughness.

Thus, a simple and efficient manufacturing method and structure for a full-color active matrix organic electroluminescent device capable of increasing the performance and reliability thereof is desirable.

### SUMMARY

Systems for displaying images are provided. In this regard, an exemplary embodiment of such as system comprises an electroluminescent device, such as a full-color active matrix organic electroluminescent device, comprising a plurality of pixel areas. An ink-jet printing color filter layer is formed in each pixel area. Each ink-jet printing color filter layer is surrounded with a dam. A planarization layer is formed on the pixel areas, covering the ink-jet printing color filter layers and the dams. An organic light emitting diode, comprising an anode electrode, electroluminescent layers, and a cathode electrode, is formed on the planarization layer, directly over the ink-jet printing color filter layer.

Methods for fabricating the system for displaying images are also provided, in which a thin film transistor array substrate with a plurality of pixel areas is provided. An insulating layer is formed on each pixel area, wherein a partial surface of the insulating layer is defined as a predetermined color filter area. A plurality of dams is formed to surround each predetermined color filter area respectively. RGB color filter layers are respectively formed in the corresponding predetermined color filter areas by ink-jet printing. A planarization layer is blanketly formed on the substrate. Organic light emitting diodes are formed on the planarization layer, directly over the color filter layers.

A detailed description is given in the following with reference to the accompanying drawings.

### BRIEF DESCRIPTION OF THE DRAWINGS

The invention can be more fully understood by reading the subsequent detailed description in conjunction with the examples and references made to the accompanying drawings, wherein:

FIG. 1 is a partial schematic top view of an organic electroluminescent device according to an embodiment of the invention.

FIGS. 2a to 2g are cross-sections showing a method of fabricating an organic electroluminescent device according to an embodiment of the invention.

FIG. 3 is a partial schematic top view of an active matrix organic electroluminescent device according to an embodiment of the invention.

FIG. 4 is a schematic top view of an organic electroluminescent device according to an embodiment of the invention.

FIG. 5 schematically shows another embodiment of a system for displaying images.

### DETAILED DESCRIPTION

In the systems for displaying images comprising electroluminescent devices of the invention, RGB color filter layers are formed by ink-jet printing, and a dam structure defines the locations of each RGB color filter layer. The following embodiments are intended to illustrate the invention more fully without limiting the scope of the claims, since numerous modifications and variations will be apparent to those skilled in this art.

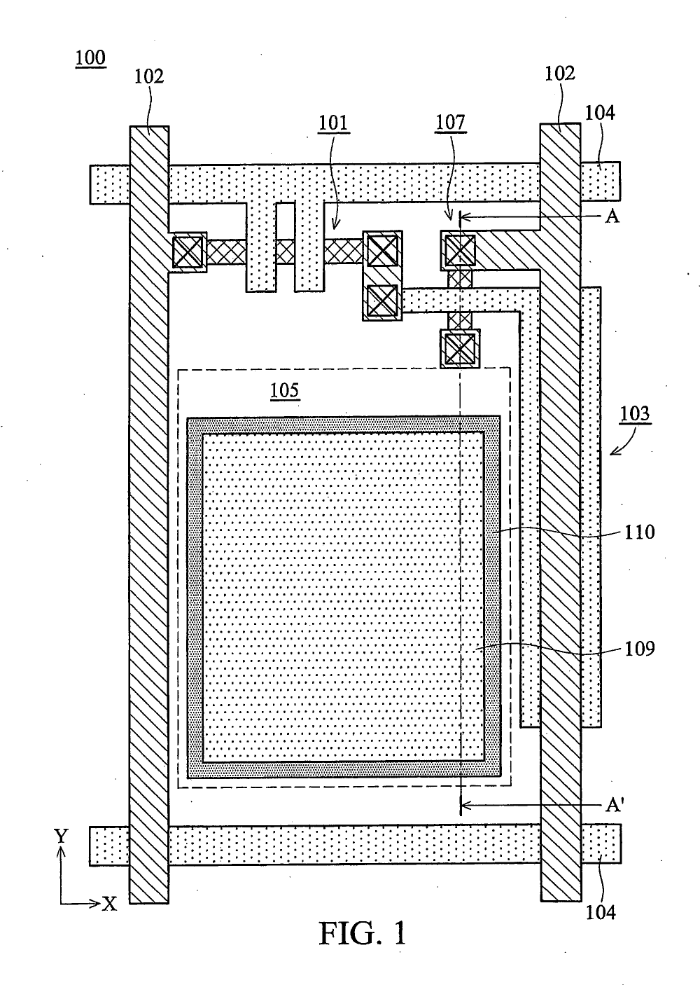

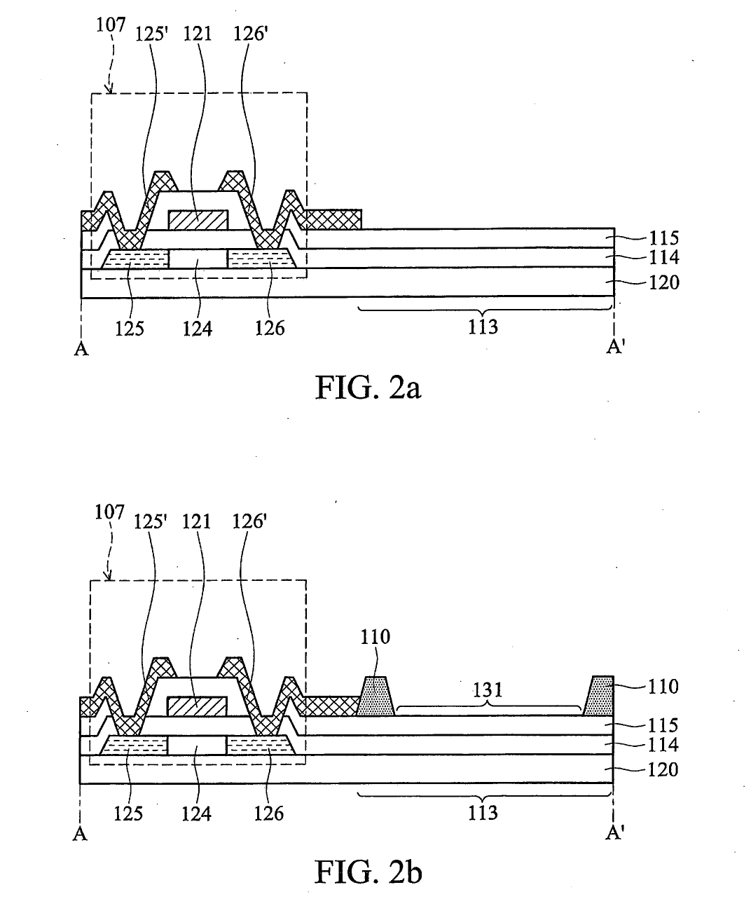

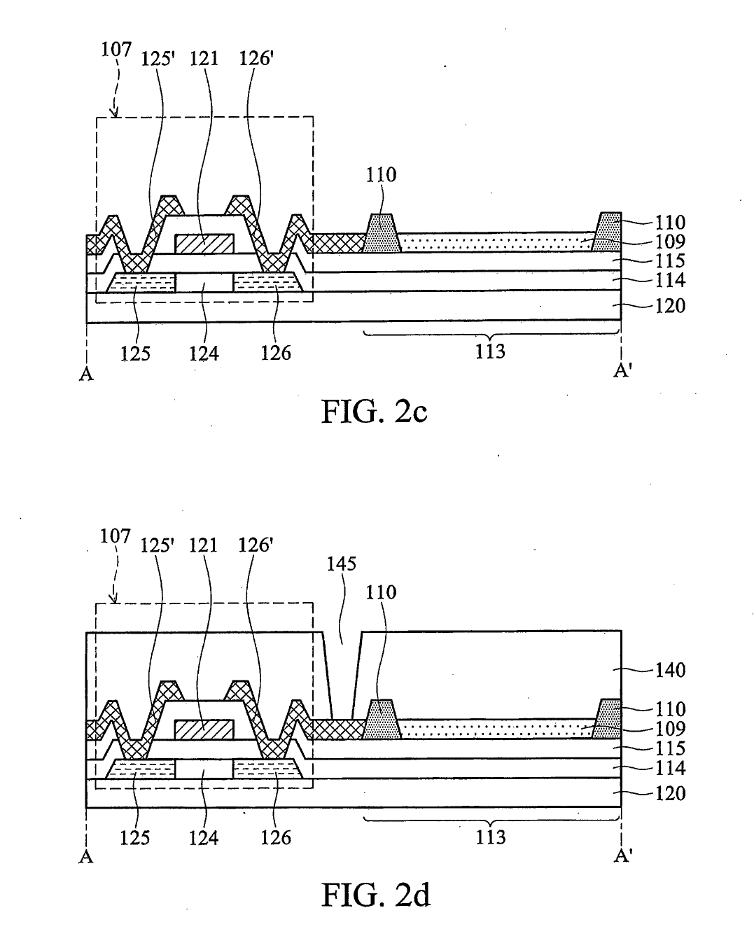

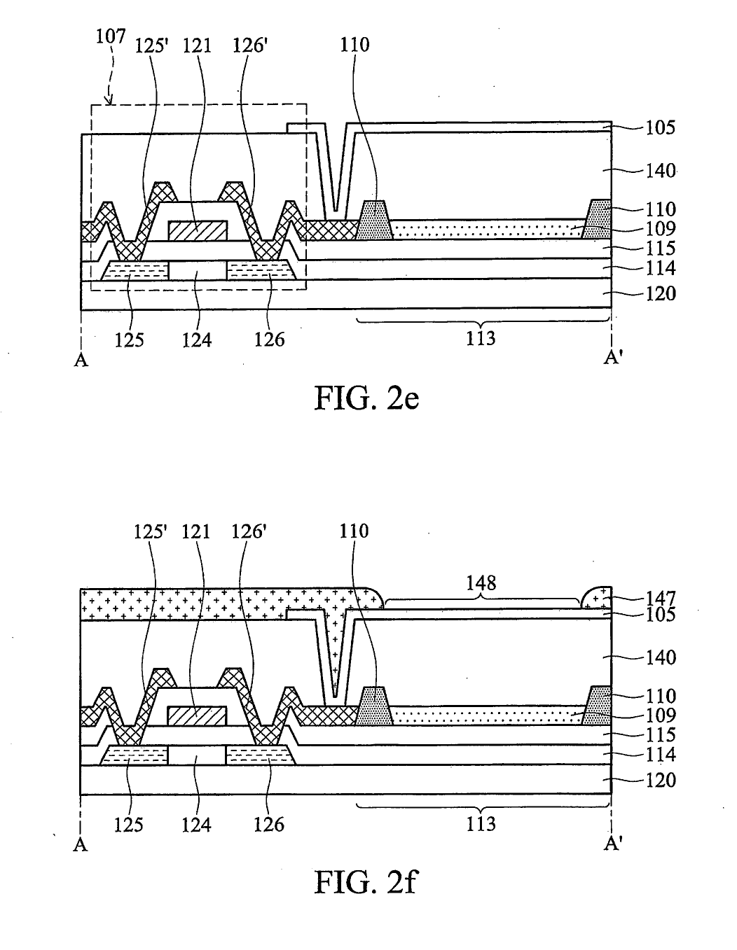

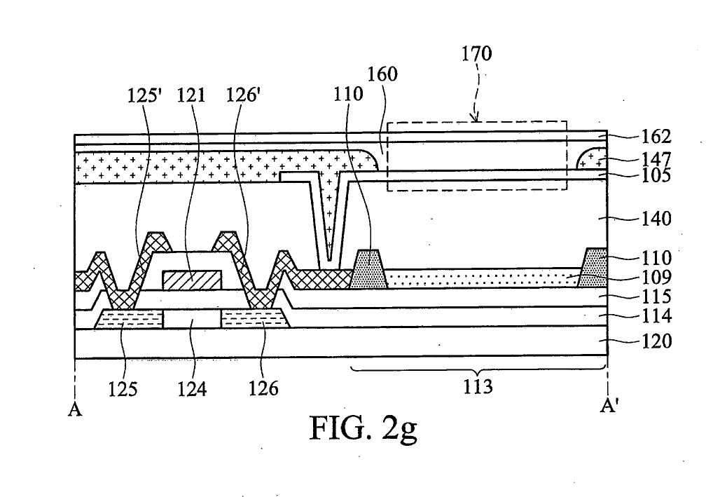

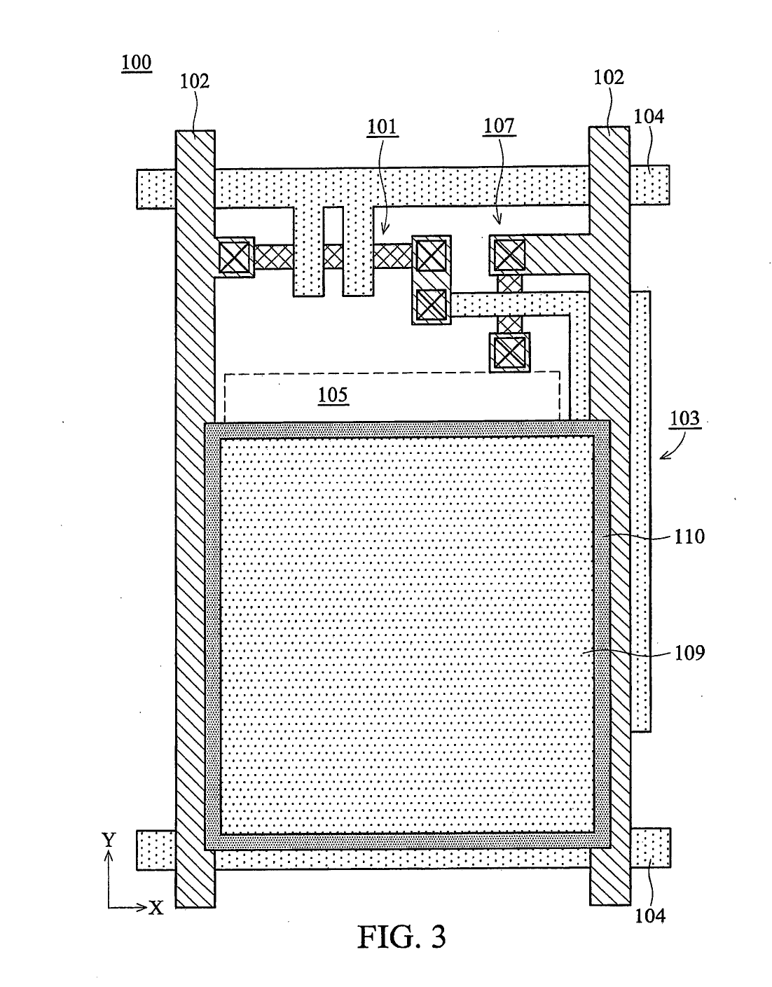

FIG. 1 is a schematic top view of a pixel area of an active matrix electroluminescent device 100 according to an embodiment of the invention. The electroluminescent device 100 comprises a plurality of pixel areas arranged in a matrix. Each pixel area comprises a TFT 101 electrically connected to a data line 102 extending along a Y direction, a scan line 104 extending along an X direction, a capacitor 103, a transparent anode electrode 105 of an organic light emitting diode, and another TFT 107 electrically connecting to the anode electrode 105 and a power line 108. Specifically, an ink-jet color filter layer 109, surrounded by a dam 110, is formed under the transparent anode electrode 105. FIGS. 2a to 2g are sectional diagrams along line A-A′ of FIG. 1 illustrating the manufacturing process of the electroluminescent device according to the systems for displaying images of embodiment of the invention.

As shown in FIG. 2a, a substrate 120 with a pixel area 113 is provided. The TFT 107 is formed on the substrate 120, and a gate dielectric layer 114 and an insulation layer 115 are disposed on the pixel area 113. The TFT 107 comprises a semiconductor layer 124, a gate electrode 121, a dielectric layer 123, a source region 125, and a drain region 126. The choices for the TFT 107 are unlimited, and can be amorphous-silicon thin film transistor, low temperature poly-silicon thin film transistor (LTPS-TFT), or organic thin film transistor (OTFT), and the structure of the TFT 107 is illustrated as an example, but not intended to be limitative of the invention. Further, the TFT 107 can also comprise a source electrode 125′ and a drain electrode 126′, wherein the source electrode 125′ and the drain electrode 126′ electrically connect to the source region 125 and drain region 126 respectively. The gate electrode 121 and the scan line 104 are of the same material and formed by the same process, and the data line 102 and the source and drain electrodes 125′ and 126′ of the same material and formed by the same process. Herein, the substrate 120 is a transparent insulating material such as glass or plastic. The gate dielectric layer 114 can comprise silicon nitride, silicon oxide, or a laminate thereof.

As shown in FIG. 2b, a dam 110, with a hollow square configuration, is formed on the insulating layer 115 in the pixel area 113, surrounding a predetermined color filter area 131. The profile of the dam is illustrated as an example, but is not intended to be limitative of the invention, and can be a quadrilateral-shape, a taper-shape, or an inverted-taper-shape. Preferably, the dam is formed by a photolithography process employing a positive photoresist, preventing accumulation of photoresist residue on the drain electrodes 126′. In some embodiments, the dam can also be made of dielectric material and patterned by etching.

As shown in FIG. 2c, a color filter layer 109 is formed on the predetermined color filter area 113 by ink-jet printing, resulting in being surrounded by the dam. Wherein, the color filter layer 109 can be optionally alternated between different colors. For example, red, green, and blue resins are injected into the corresponding predetermined color filter areas. In the ink-jet printing process, the RGB color filter layers can be formed simultaneously or batchwise. Moreover, two different color filters can also be used to produce full color images. As a main feature and a key aspect, the height ratio between the dam and the ink-jet printing color filter layer must be in the range of 3:1˜20:19, preferably 2:1˜4:3, preventing the color filter ink from overflowing the dam into the drain electrode 126′, further avoiding open circuit and contact blind.

As shown in FIG. 2d, a planarization layer 140 is blanketly formed on the substrate 120, covering the ink-jet printing color filter layer and the dam. Herein, the planarization layer 140 can be organic resin film or dielectric or insulator materials such as dielectric material or spin-on glass (SOG). Next, a via hole 145 is formed to pass through the planarization layer 140, exposing the drain electrode 126′.

As shown in FIG. 2e, a transparent conductive layer is formed on the planarization layer 140 and patterned to form transparent anode electrode 105 of an organic light emitting diode, electrically connected to the drain electrode 126′ through the via hole 145. Suitable material for the transparent anode electrode 105 is transparent metal or metal oxide, such as indium tin oxide (ITO), indium zinc oxide (IZO), aluminum zinc oxide (AZO), or zinc oxide (ZnO). Preferably, the transparent anode electrode 105 is formed by sputtering, electron beam evaporation, thermal evaporation, or chemical vapor deposition.

As shown in FIG. 2f, a patterned pixel definition layer 147 is formed on the substrate, exposing the surface 148 of the transparent anode electrode 105 directly over the color filter layer 109. Materials of the pixel definition layer 147 can be materials suitable for use in photoelectric devices, such as photo-curable resin or thermal-curable resin.

As shown in FIG. 2g, electroluminescent layers 160 and a cathode electrode 162 are sequentially formed on the substrate 120. The electroluminescent layers 160 may comprise a hole injection layer, a hole transport layer, an emission layer, and an electron transport layer, including organic semiconductor materials, such as small molecule materials, polymer, or organometallic complex, formed by thermal vacuum evaporation, spin coating, dip coating, roll-coating, injection-filling, embossing, stamping, physical vapor deposition, or chemical vapor deposition. The cathode electrode 162 can be capable of injecting electrons into an organic electroluminescent layer, for example, a low work function material such as Ca, Ag, Mg, Al, Li, or alloys thereof. The anode electrode 105, the electroluminescent layers 160, and the cathode electrode 162, directly over the color filter layer 109, comprise an organic light emitting diode 170.

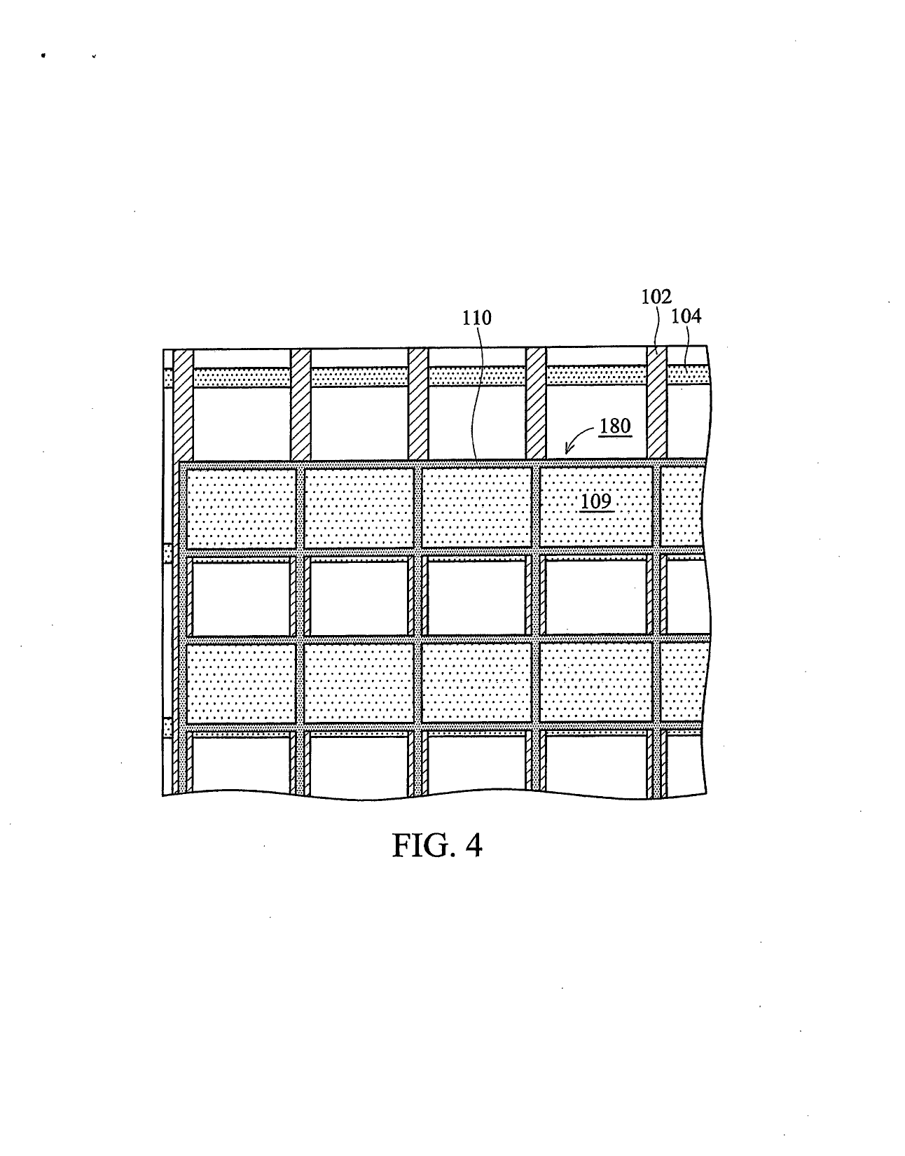

According to another embodiment of the invention, in order to improve the aperture ratio of the organic electroluminescent device, the dam 110 can be further formed over the data line 102 and the scan line 104, as shown in the FIG. 3, thereby increasing the dimensions of the color filter layer. Moreover, the dams of each pixel can connect each other to construct a grid-shaped structure 180, as shown in FIG. 4, simplifying the patterning complexity of dam 110.

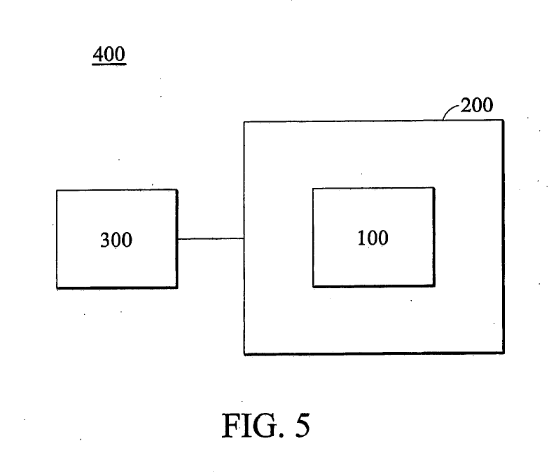

FIG. 5 schematically shows another embodiment of a system for displaying images which, in this case, is implemented as a display panel 200 or an electronic device 400. The described active matrix organic electroluminescent device can be incorporated into a display panel that can be an OLED panel. As shown in FIG. 5, the display panel 200 comprises an active matrix organic electroluminescent device, such as the active matrix organic electroluminescent device 100 shown in FIG. 1 and FIG. 3. The display panel 200 can form a portion of a variety of electronic devices (in this case, electronic device 400). Generally, the electronic device 400 can comprise the display panel 200 and an input unit 300. Further, the input unit 300 is operatively coupled to the display panel 200 and provides input signals (e.g., an image signal) to the display panel 400 to generate images. The electronic device 400 can be a mobile phone, digital camera, personal digital assistant (PDA), notebook computer, desktop computer, television, car display, or portable DVD player, for example.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A system for displaying images, comprising:
an electroluminescent device, comprising
a plurality of pixel areas;
an ink-jet printing color filter layer formed in each pixel area;
a dam surrounding the ink-jet printing color filter layer;
a planarization layer formed on the ink-jet printing color filter layer and the dam; and
an organic light diode formed on the planarization layer, directly over the ink-jet printing color filter layer.

2. The system as claimed in claim 1, wherein the dam is cured in positive type photoresist.

3. The system as claimed in claim 1, wherein the dam is a dielectric material.

4. The system as claimed in claim 1, wherein the height ratio between the dam and the ink-jet printing color filter layer is 3:1˜20:19.

5. The system as claimed in claim 1, wherein the height ratio between the dam and the ink-jet printing color filter layer is 2:1˜4:3.

6. The system as claimed in claim 1, wherein the profile of the dam is quadrilateral-shaped, taper-shaped, or inverted-taper-shaped.

7. The system as claimed in claim 1, further comprising a scan line and a data line, directly under the dam.

8. The system as claimed in claim 1, wherein the dams of the plurality of pixel areas construct a grid-shaped structure.

9. The system as claimed in claim 1, further comprising a display panel, wherein the electroluminescent device forms a portion of the display panel.

10. The system as claimed in claim 9, further comprising an electronic device, wherein the electronic device comprises:
the display panel; and
an input unit coupled to the display panel and operative to provide input to the display panel such that the display panel displays images.

11. The system as claimed in claim 10, wherein the electronic device is a mobile phone, digital camera, PDA (personal digital assistant), notebook computer, desktop computer, television, car display, or portable DVD player.

12. A method of fabricating a system for displaying images, wherein the system comprising an electroluminescent device, the method comprising:
providing a thin film transistor array substrate with a plurality of pixel areas;
forming an insulating layer on each pixel area, wherein a partial surface of the insulating layer is defined as a predetermined color filter area;
forming dams surrounding each predetermined color filter area;
forming a color filter layer in the predetermined color filter area by ink-jet printing;
blanketly forming a planarization layer on the substrate; and
forming an organic light emitting diode on the planarization layer, directly over the color filter layer.

13. The method as claimed in claim 12, wherein the dam is cured in positive type photoresist.

14. The method as claimed in claim 12, wherein the dam is a dielectric material.

15. The method as claimed in claim 12, wherein the height ratio between the dam and the ink-jet printing color filter layer is 3:1˜20:19.

16. The method as claimed in claim 12, wherein the height ratio between the dam and the ink-jet printing color filter layer is 2:1˜4:3.

17. The method as claimed in claim 12, wherein the profile of the dam is quadrilateral-shaped, taper-shaped, or inverted-taper-shaped.

18. The method as claimed in claim 12, wherein the thin film transistor array substrate comprises a plurality of scan lines and data lines directly under the dams.

19. The method as claimed in claim 12, wherein the dams construct a grid-shaped structure.
